(19) United States
(12) Patent Application Publication
(10) Pub. No.: US 2015/0004775 A1
(43) Pub. Date: Jan. 1, 2015

(54) SEMICONDUCTOR NANOCRYSTALS, METHODS FOR PREPARING SEMICONDUCTOR NANOCRYSTALS, AND PRODUCTS INCLUDING SAME

(71) Applicant: QD VISION, INC., LEXINGTON, MA (US)

(72) Inventors: DIYUN HUANG, FREMONT, CA (US); JONATHAN S. STECKEL, CARLISLE, MA (US)

(21) Appl. No.: 14/296,185

(22) Filed: Jun. 4, 2014

Related U.S. Application Data
(60) Provisional application No. 61/834,815, filed on Jun. 13, 2013.

(51) Int. Cl. H01L 21/02; H01L 29/06; H01L 29/24

(52) U.S. Cl. CPC H01L 21/02598; H01L 29/24; H01L 29/0665
USPC 438/478; 423/303; 252/519.14

(57) ABSTRACT

Disclosed is a method for preparing a semiconductor nanocrystal, comprising: forming a reaction mixture comprising injecting one or more first semiconductor nanocrystal precursors including one or more Group V elements and one or more Group VI elements into a mixture including one or more second semiconductor nanocrystal precursors including one or more Group II elements and one or more Group III elements at a first temperature; and reacting the first and second semiconductor nanocrystal precursors in the reaction mixture at a second temperature for a period time sufficient to form a semiconductor nanocrystal core comprising at least a portion of the one or more Group II elements, one or more Group III elements, one or more Group V elements, and one or more Group VI elements included in the first and second semiconductor nanocrystal precursors, wherein the second temperature is greater than the first temperature.

This application claims priority to U.S. Provisional Patent Application No. 61/834,815, filed on 13 Jun. 2013, which is hereby incorporated herein by reference in its entirety for all purposes.

### FEDERALLY SPONSORED RESEARCH OR DEVELOPMENT

This invention was made with Government support under Advanced Technology Program Award No. 70NANB7H7056 awarded by NIST. The United States has certain rights in the invention.

### TECHNICAL FIELD OF THE INVENTION

The present invention relates to the field of nanotechnology.

### SUMMARY OF THE INVENTION

The present invention relates to methods for preparing semiconductor nanocrystals, semiconductor nanocrystals prepared thereby, and end-use applications including semiconductor nanocrystals.

In accordance with one aspect of the present invention, there is provided a method for preparing a semiconductor nanocrystal, comprising: forming a reaction mixture comprising injecting one or more first semiconductor nanocrystal precursors including one or more Group V elements and one or more Group VI elements into a mixture including one or more second semiconductor nanocrystal precursors including one or more Group II elements and one or more Group III elements at a first temperature; and reacting the first and second semiconductor nanocrystal precursors in the reaction mixture at a second temperature for a period time sufficient to form a semiconductor nanocrystal core comprising at least a portion of the one or more Group II elements, one or more Group III elements, one or more Group V elements, and one or more Group VI elements included in the first and second semiconductor nanocrystal precursors, wherein the second temperature is greater than the first temperature.

In one aspect, a reaction mixture including semiconductor nanocrystal precursors including zinc, indium, gallium, phosphorus, and sulfur is used to prepare semiconductor nanocrystal cores with a peak emission in the blue or green spectral region.

In one aspect, a reaction mixture including semiconductor nanocrystal precursors including zinc, indium, gallium, phosphorus, and sulfur is used to prepare semiconductor nanocrystal cores with a peak emission in the blue spectral region.

The inclusion of gallium in the reaction mixture can provide a blue shift in the peak emission wavelength of the resulting semiconductor nanocrystal core compared to a core prepared under similar reaction conditions from a reaction mixture that does not include gallium but is otherwise the same.

The method can further include overcoating the semiconductor nanocrystal cores with one or more inorganic semiconductor materials. An overcoating can comprise one or more layers, at least one of which comprises an inorganic semiconductor material. When an overcoating includes more than one layer, any layer can comprise a material that is the same as or different from that included in another layer.

Preferably, the semiconductor nanocrystal cores are isolated prior to the overcoating step.

In certain aspects, a reaction mixture includes zinc, indium, gallium, phosphorus, and sulfur.

In accordance with another aspect of the present invention, there is provided a semiconductor nanocrystal prepared by a method taught herein.

In accordance with another aspect of the present invention, there is provided a light emitting device including an emissive material comprising a semiconductor nanocrystal prepared by a method taught herein.

The foregoing, and other aspects and embodiments described herein all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### DETAILED DESCRIPTION OF THE INVENTION

For a better understanding of the present invention, together with advantages and capabilities thereof, reference is made to the following disclosure.

Various aspects and embodiments of the present inventions will be further described in the following detailed description.

The present invention relates to methods and reactions for preparing semiconductor nanocrystals. Semiconductor nanocrystals as prepared herein may further be provided with an overcoating comprising an inorganic semiconductor material. An overcoating can include one or more layers, at least one of which comprises an inorganic semiconductor material. When an overcoating includes more than one layer, any layer can comprise a material that is the same as or different from that included in another layer. The present invention further relates to semiconductor nanocrystals formed by the methods described herein. The present invention further also relates to end-use applications of semiconductor nanocrystals formed by the methods described herein.

A semiconductor nanocrystal may also be referred to herein as a semiconductor nanoparticle, a nanocrystal, or a quantum dot.

As described above, in accordance with one aspect of the present invention, a method for preparing a semiconductor nanocrystal, comprising: forming a reaction mixture by injecting one or more first semiconductor nanocrystal precursors including one or more Group V elements and one or more Group VI elements into a mixture including one or more second semiconductor nanocrystal precursors including one or more Group II elements and one or more Group III elements at a first temperature; and reacting the first and second semiconductor nanocrystal precursors in the reaction mixture at a second temperature for a period time sufficient to form a semiconductor nanocrystal core comprising at least a portion of the one or more Group II elements, one or more Group III elements, one or more Group V elements, and one or more Group VI elements included in the first and second semiconductor nanocrystal precursors, wherein the second temperature is greater than the first temperature.

Group II elements include the elements of Group IIB (e.g., Zn, Cd, Hg) of the Periodic Table.

Group III elements include the elements of Group IIIA (e.g., Al, Ga, In, Ti) of the Periodic Table.

Group V elements include the elements of Group VA (e.g., N, P, As, Sb) of the Periodic Table.

Group VI elements include the elements of Group VIA (e.g., O, S, Se, Te) of the Periodic Table.

In the methods described herein, the one or more semiconductor nanocrystal precursors are selected based on the composition of the semiconductor nanocrystals being prepared.

Examples of Group II precursors include, but are not limited to, Group II elements (oxidation state 0), covalent compounds, ionic compounds, and/or coordination complexes, that serve as a source for a Group II element(s) in the resulting nanocrystal. For example, a Group II precursor can constitute a wide range of substances, including, but not limited to, a metal oxide, a metal carbonate, a metal bicarbonate, a metal sulfate, a metal sulfite, a metal phosphate, metal phosphite, a metal phosphonate, a metal halide, a metal carboxylate, other metal salts, a metal alkoxide, a metal thiolate, a metal amide, a metal imide, a metal alkyl, a metal aryl, other organometallic compounds, a metal coordination complex, a metal solvate, etc., wherein the metal comprises a Group II element. For example, non-limiting examples of zinc precursors include Zn (II) carboxylates (e.g., but not limited to, acetates, stearates, etc.), dialkyl zinc (ZnR₂) wherein R=methyl, ethyl, propyl, butyl, pentyl, hexyl, isopropyl, isobutyl, tert-butyl, etc.). Other Group II precursors can be readily ascertained by one of ordinary skill in the art.

Optionally, a mixture of two or more different precursors for the same Group II element can be included. For example, a mixture of zinc acetate and zinc stearate can be included as the Zn precursor in the mixture.

Examples of Group III precursors include, but are not limited to, Group III elements (oxidation state 0), covalent compounds, ionic compounds, and/or coordination complexes, that serve as a source for a Group III element(s) in the resulting nanocrystal. For example, a Group III precursor can constitute a wide range of substances, including, but not limited to, a metal oxide, a metal carbonate, a metal bicarbonate, a metal sulfate, a metal sulfite, a metal phosphate, metal phosphite, a metal phosphonate, a metal halide, a metal carboxylate, other metal salts, a metal alkoxide, a metal thiolate, a metal amide, a metal imide, a metal alkyl, a metal aryl, other organometallic compounds, a metal coordination complex, a metal solvate, etc., wherein the metal comprises a Group III element For example, non-limiting examples of indium precursors include In(III) carboxylates (e.g., but not limited to, acetates (including, but not limited to, In(III) acetate, In(III) trifluoroacetate), stearates, etc.), trialkyl indium (InR₃) (wherein R=methyl, ethyl, propyl, butyl, pentyl, hexyl, isopropyl, isobutyl, tert-butyl, etc.); non-limiting examples of gallium precursors include Ga(III) carboxylates (e.g., but not limited to, acetates (including, but not limited to, Ga(III) acetate, Ga(III) trifluoroacetate, trialkyl gallium (GaR₃) (wherein R=methyl, ethyl, propyl, butyl, pentyl, hexyl, isopropyl, isobutyl, tert-butyl, etc.). Other Group III precursors can be readily ascertained by one of ordinary skill in the art.

Optionally, a mixture of two or more different precursors for the same Group III element can be included.

In certain embodiments, for example, Group III elements included in the mixture include indium and gallium. Inclusion of gallium can provide a blue shift in the peak emission wavelength of the resulting semiconductor nanocrystal core compared to one prepared under similar reaction conditions from a reaction mixture that does not include gallium but is otherwise the same. Such blue shift can be desirable if preparing, for example, blue-emitting semiconductor nanocrystals cores.

In certain embodiments, for example, a molar ratio of indium to gallium can be in a range from 1:0.5 to 1.1 can be used. Other ratios may be found to be useful or desirable. In certain embodiments, a ratio of 1:0.5 may provide a 15 nm blue shift.

Examples of Group V precursors include Group V elements (oxidation state 0), covalent compounds, or ionic compounds that serve as a source for a Group V element(s) in the resulting nanocrystal. Group V precursors are most often selected from the Group V elements themselves (oxidation state 0), covalent compounds, or ionic compounds of the group V elements (N, P, As, or Sb). For example, non-limiting examples of phosphorus precursors include P(SiR₃)₃ wherein R=methyl, ethyl, propyl, butyl, pentyl, hexyl, isopropyl, isobutyl, tert-butyl, etc.), and phosphine. Other Group V precursors can be readily ascertained by one of ordinary skill in the art.

Optionally, a mixture of two or more different precursors for the same Group V element can be included.

Examples of Group VI precursors include Group VI elements (oxidation state 0), covalent compounds, or ionic compounds that serve as a source for a Group VI element(s) in the resulting nanocrystal. For example, non-limiting examples Group VI precursors include comprise oxygen, sulfur, selenium, tellurium, or mixtures thereof, reactive chalcogenide sources, such as bis(trimethylsilyl) selenide (TMS)₂Se, bis(trimethylsilyl)sulfide (TMS)₂S, H₂S, octadecene-Se, (ODE/Se), octadecene-S (ODE/s), amine-Se, amine-S, oxygen-treated tertiary phosphine chalcogenide and mixtures thereof, secondary phosphine chalcogenides (including secondary phosphine sulfides, secondary phosphine selenides, secondary phosphine tellurides, a secondary phosphine oxides, dialkyl phosphine chalcogenides (including iisobutylphosphine selenides, diisobutylphosphine sulfides, diphenylphosphine selenides, diphenylphosphine sulfides or mixtures thereof), or mixtures of any of the above. Other Group VI precursors can be readily ascertained by one of ordinary skill in the art.

Optionally, a mixture of two or more different precursors for the same Group VI element can be included.

Within the scope of the present invention, one or more second semiconductor nanocrystal precursors including one or more Group II elements and one or more semiconductor nanocrystal precursors including one or more Group III elements, the precursors being selected based on the Group II and Group III elements included in desired composition of the semiconductor nanocrystal core being prepared, are combined, forming a mixture.

The mixture can further include a liquid medium. Examples of a liquid medium include coordinating solvents, weakly coordinating solvents, and non-coordinating solvents. A solvent can also comprise a mixture of solvents. Preferably, the liquid medium comprises a non-aqueous solvent. Examples of non-coordinating solvents that can be desirable for use in the methods taught herein include, but are not limited to, squalane, octadecane, or any other saturated hydrocarbon molecule. A coordinating solvent is a compound having a donor lone pair, for example, a lone electron pair available to coordinate to a surface of a semiconductor nanocrystal. Solvent coordination can stabilize the growing of semiconductor nanocrystal cores or growing of an overcoating thereon. Examples of coordinating solvents include, without limitation, alkyl phosphines, alkyl phosphine oxides, alkyl phosphonic acids, or alkyl phosphinic acids, however, other coordinating solvents, such as pyridines, furans, and amines may also be suitable for the semiconductor nanocrystal (e.g., semiconductor nanocrystal) production. Additional examples of suitable coordinating solvents include pyridine, tri-n-octyl phosphine (TOP), tri-n-octyl phosphine oxide (TOPO) and trishydroxylpropylphosphine (tHPP), tributylphosphine, tri(dodecyl)phosphine, dibutyl-phosphite, tributyl phosphite, trioctadecyl phosphite, trilauryl phosphite, tris(tridecyl) phosphite, triisodecyl phosphite, bis(2-ethylhexyl)phosphate, tris(tridecyl) phosphate, hexadecylamine, oleylamine, octadecylamine, bis(2-ethylhexyl)amine, octylamine, dioctylamine, trioctylamine, dodecylamine/laurylamine, didodecylamine tridodecylamine, hexadecylamine, dioctadecylamine, trioctadecylamine, phenylphosphonic acid, hexylphosphonic acid, tetradecylphosphonic acid, octylphosphonic acid, octadecylphosphonic acid, propylenediphosphonic acid, phenylphosphonic acid, aminohexylphosphonic acid, dioctyl ether, diphenyl ether, methyl myristate, octyl octanoate, N-dodecylpyrrolidone (NDP), and hexyl octanoate. In certain embodiments, technical grade TOPO can be used. Other solvents for use in the methods taught herein can be readily ascertained by one of ordinary skill in the art.

In certain aspects, a non-coordinating solvent may be preferred.

According to one aspect, the mixture can further include one or more carboxylic acid compounds.

As used herein, a “carboxylic acid compound” refers to a compound including at least one carboxylic acid or carboxylate group. Carboxylic acid compounds may have one or more alkyl and/or aryl groups, that, in either or both cases, can be independently substituted or unsubstituted. In certain embodiments a carboxylic compound can be a mixture including one or more carboxylic acid compounds. Examples of carboxylic acid compounds include, but are not limited to, CH₃(CH₂)ₙC(O)OH wherein n=1-18, e.g, CH₃(CH₂)ₙC(O)OH wherein n=6-18, and carboxylate salts thereof. Additional examples of particular carboxylic acid compounds include octanoic [caprylic] acid, nonanoic [pelargonic] acid, decanoic [capric] acid, undecanoic acid, dodecanoic [lauric] acid, tridecanoic acid, tetradecanoic [myristic] acid, pentadecanoic acid, hexadecanoic [palmitic] acid, heptadecanoic [margaric] acid, octadecanoic [stearic] acid, nonadecanoic acid, eicosanoic [arachidic] acid or oleic acid, and carboxylate salts thereof. According to a certain aspect, the carboxylic acid compound is a myristic acid compound or a myristate salt. Other carboxylic acid compounds for use in the method can be identified by one of ordinary skill in the art.

Exemplary carboxylic acid compounds include, but are not limited to, myristic acid and stearic acid.

According to one aspect, the mixture and the reaction mixture are oxygen free. According to one aspect, each of the precursors and solvents are degassed.

According to one aspect, the method is carried out under oxygen-free conditions.

Within the scope of the present invention, one or more first semiconductor nanocrystal precursors including one or more Group V elements and one or more semiconductor nanocrystal precursors including one or more Group VI elements, the precursors being selected based on the Group V and Group VI elements included in the desired composition of the semiconductor nanocrystal core being prepared, are injected into the mixture, forming a reaction mixture.

According to one aspect, one or more semiconductor nanocrystal precursors including one or more Group V elements and one or more semiconductor nanocrystal precursors including one or more Group VI elements can be added to mixture simultaneously.

If more than one semiconductor nanocrystal precursor including one or more Group V elements is used, they can be injected as a mixture or each can be separately injected. Likewise, if more than one semiconductor nanocrystal precursor including one or more Group VI elements is used, they can be injected as a mixture or each can be separately injected.

According to one aspect, one or more semiconductor nanocrystal precursors including one or more Group V elements and one or more semiconductor nanocrystal precursors including one or more Group VI elements can be added to mixture sequentially.

According to one aspect, a semiconductor nanocrystal precursor can be added to mixture as a single addition.

According to one aspect, a semiconductor nanocrystal precursor can be added to mixture as a series of addition.

Within the scope of the present method, the reaction mixture includes various precursors that are selected, and included in the reaction mixture in amounts selected, to prepare a semiconductor nanocrystal core having the desired composition, size, and emission wavelength. Such determination is within the skill of the person of ordinary skill in the relevant art.

In certain embodiments, first and second semiconductor nanocrystal precursors are included in amounts to form a reaction mixture including Group II elements, Group III elements, Group V elements, and Group VI elements wherein the molar ratio of Group II elements to Group III elements to Group V elements to Group VI elements is approximately 1 to 1 to 1 to 1.

If one or more carboxylic acid compounds are further included in the reaction mixture, it can be desirable to include carboxylic acid compounds in the reaction mixture in a molar amount that is from about 1.5 to 4 (e.g., including, but not limited to, approximately 2 to 3) times the molar amount of the Group III elements.

Within the scope of the present invention, forming a reaction mixture comprises injecting one or more first semiconductor nanocrystal precursors including one or more Group V elements and one or more Group VI elements into a mixture including one or more second semiconductor nanocrystal precursors including one or more Group II elements and one or more Group III elements at a first temperature.

In one aspect, the first temperature is greater than 170° C., e.g., greater than or equal to 200° C. An exemplary first temperature is within the range from about 200° C. to about 250° C. A specific exemplary first temperature is about 245° C. Other first temperatures within the scope of the present disclosure can also be used.

Within the scope of the present invention, after the reaction mixture is formed, the method comprises reacting the first and second semiconductor nanocrystal precursors in the reaction mixture at a second temperature for a period time sufficient to form a semiconductor nanocrystal core comprising at least a portion of the one or more Group II elements, one or more Group III elements, one or more Group V elements, and one or more Group VI elements included in the first and second semiconductor nanocrystal precursors, wherein the second temperature is greater than the first temperature.

In one aspect, the second temperature is greater than 250° C., e.g., greater than or equal to 255° C. Preferably the second temperature is at least 10° C. greater than the first temperature. An exemplary second temperature is within the range from about 255° C. to about 325° C. A specific exemplary second temperature is about 275° C. Other second temperatures within the scope of the present disclosure can also be used.

In a certain embodiments, the reacting step is carried out at a single second temperature, for example, the temperature control is not changed until the reaction is terminated or ended.

A first temperature of 245° C. and a second temperature of 275° C. can be preferred for use in carrying out the method.

In various aspects, the mixture and/or reaction mixture can further include one or more ligands.

Ligands can be derived from a coordinating solvent that may be included in the reaction mixture during the growth process. Alternatively, ligands can be added to the reaction mixture or ligands can be derived from a reagent or precursor included in the reaction mixture for synthesizing the semiconductor nanocrystals. In certain embodiments, semiconductor nanocrystals can include more than one type of ligand attached to an outer surface.

Examples of ligands include, but are not limited to, fatty acids and other carboxylic acid compounds, phosphonic acid compounds, amine compounds, phosphines, phosphine oxides, etc. Examples of additional ligands include fatty acids, long chain fatty acids such as oleic acid, alkyl phosphines, alkyl phosphine oxides, alkyl phosphonic acids, or alkyl phosphinic acids, pyridines, furans, and amines. More specific examples include, but are not limited to, pyridine, tri-n-octyl phosphine (TOP), tri-n-octyl phosphine oxide (TOPO), tris-hydroxylpropylphosphine (tHPP) and octadecylphosphonic acid (“ODPA”). Technical grade TOPO can be used.

In certain embodiments, the ligands include phenylbutyl amine, decyl amine, benzylphosphonic acid, and/or octadecyl phosphonic acid.

Suitable coordinating ligands can be purchased commercially or prepared by ordinary synthetic organic techniques readily ascertainable by the skilled artisan.

Within the scope of the present invention, the method described herein can further include growing an overcoating comprising one or more semiconductor materials over at least a portion of an outer surface of at least a portion of the semiconductor nanocrystal cores. A coating can further comprise one or more layers, each of which can be the same as, or different from, another layer in the coating.

In one aspect, overcoating comprises adding one or more overcoating precursors to the semiconductor nanocrystal cores included a liquid medium, and reacting the overcoating precursors to form an overcoating comprising one or more semiconductor materials over at least a portion of an outer surface of at least a portion of the semiconductor nanocrystal cores.

Optionally, the overcoating mixture can further include one or more ligands. Examples of such ligands can include, without limitation, ligands discussed elsewhere herein.

According to one aspect, the overcoating step carried out under oxygen-free conditions.

The overcoating can include one or more semiconductor materials having a composition different from the composition of the core and can have a band gap greater than the band gap of the core. The overcoat of a semiconductor material on a surface of the nanocrystal can include a Group II-VI compounds, Group II-V compounds, Group III-VI compounds, Group III-V compounds, Group IV-VI compounds, Group compounds, Group II-IV-VI compounds, and Group II-IV-V compounds, with Group I referring to Group IB (e.g., Cu, Ag, Au) of the Periodic Table, Group II referring to Group JIB (e.g., Zn, Cd, Hg) of the Periodic Table, Group III referring to Group IIIA (e.g., Al, Ga, In, TI) of the Periodic Table, Group IV (e.g., Si, Ge) of the Periodic Table, Group V referring to Group VA (e.g., N, P, As, Sb) of the Periodic Table (Group V elements also known as pnictogens), and Group VI referring to Group VIA (e.g., O, S, Se, Te) of the Periodic Table (Group VI elements also known as chalcogens).

One or more overcoating precursors are selected to include those elements to be included in the semiconductor material of the desired overcoating. Amounts of the overcoating precursors are selected based on the desired overcoating thickness. Such selections are within the skill of the person of ordinary skill in the relevant art.

An overcoating can have a thickness from about one to about ten monolayers. An overcoating can also have a thickness greater than ten monolayers. In certain embodiments, more than one overcoating can be included on a core.

In certain embodiments, the surrounding overcoating or “shell” material can have a band gap greater than the band gap of the core material. In certain other embodiments, the surrounding shell material can have a band gap less than the band gap of the core material.

In one embodiment, for example, a liquid medium (e.g, a solvent discussed herein, or a mixture of solvents (e.g., an aromatic solvent (e.g., o-terphenyl) and a solvent (e.g., squalene)) is preferably treated to remove oxygen (e.g., by degassing and backfilling with nitrogen). Semiconductor nanocrystal cores that have been isolated and dispersed in an organic solvent (e.g., hexane) are added to the liquid medium under oxygen free conditions. One or more ligands (e.g., phenylbutyl amine) can be added. Precursors for forming the desired overcoating material can be introduced into the liquid medium including the cores. Such introduction can be made, for example, by injection. The precursors can be added separately, which can be preferred in certain embodiments, or as a mixture. Such addition can be by controlled periodic additions using syringe pump. The overcoating step can be carried out under conditions sufficient for growing an overcoating of a desired thickness. For example, for growing a zinc sulfide overcoating, the overcoating can be carried out at a temperature greater than 200° C., e.g., 250° C., with the addition of the precursors (e.g., diethyl zinc and bis(trimethylsilyl)sulfide (S(TMS)₂) being initiated before the liquid medium including the cores reaches the desired temperature, e.g., infusion can be initiated when the temperature of the liquid medium including the cores reaches about 150° C. during the ramp of the temperature to the desired reaction temperature for the overcoating step. Optionally, additional ligands of an acidic nature (e.g., phosphonic acid ligands, including but not limited to benzylphosphonic acid) can be added, preferably by infusion at a controlled rate) after initiation of the infusion of the overcoating precursors. Following completion of the reaction, the overcoated cores are preferably isolated and purified under oxygen free conditions. Other temperatures can be used for carrying out the overcoating step and can be readily determined by the skilled artisan.

By adjusting the temperature of the reaction mixture during overcoating and monitoring the absorption spectrum of the core, overcoated materials controlled size distributions can be obtained.

The overcoating step can further include the introduction of an organic ester (represented by the formula RCOOR′ (where R and R′ represent an organic group (e.g., including an alkyl group or an aryl group), that can be the same or different). Preferred R and R′ groups include straight chain alkyl groups. A non-limiting example of a preferred organic ester for use in an overcoating step is dodecyl acetate. The introduction of an organic ester in the overcoating step can result in an increase in the solution quantum yield of the overcoated cores. Such addition can also result in a slight decrease in FWHM of the core/shell nanocrystals so prepared. In certain embodiments, the organic ester (which is less aggressive than its carboxylic acid counterpart) is introduced into the reaction vessel before introduction of the overcoating precursors. Preferably the temperature of the reaction vessel at the time the organic ester is introduced is at or near the desired reaction vessel temperature for forming the overcoating.

In certain embodiments, the shell can be chosen so as to have an atomic spacing close to that of the “core” substrate. In certain other embodiments, the shell and core materials can have the same crystal structure.

In certain embodiments, an overcoating step can include diethyl zinc and hexamethyldisilathiane (also known as bis(trimethylsilyl) sulfide)) as precursors and benzylphosphonic acid and phenylbutyal amine as a ligand pair. Such overcoating step can comprise, for example, introducing (e.g., by injection) an organic ester such as dodecyl acetate before beginning delivery of the precursors and ligand pair. Such delivery can be carried out with use of an infusion pump. A preferred infusion temperature can be 240° C. Such infusion can be carried out over a predetermined period of time. In certain examples, the predetermined period can be about 2 hours. Depending on the precursors and any ligands included in the overcoating step, and the desired thickness and other desired parameters of the core/shell nanocrystal being prepared, other temperatures and times may be determined by the skilled artisan to be useful or desirable.

The method can further include isolating or recovering the semiconductor nanocrystal cores from the reaction medium before further processing (e.g., before growth of an overcoating layer or shell on at least a portion of the outer surface of the semiconductor nanocrystal cores).

Within the scope of the present invention, it is expected that overcoated semiconductor nanocrystals including a core comprising indium, gallium, zinc, phosphorus, and sulfur, and an overcoating comprising zinc and sulfur with ligands comprising benzyl phosphonic acid and phenylbutyl amine, can be prepared that emit light at a wavelength in the range from about 470 to 480 nm, with quantum yield of at least 20-35% and FWHM around 50 nm.

Size distribution during the reaction process can be estimated by monitoring the absorption or emission line widths of the particles. Modification of the reaction temperature in response to changes in the absorption spectrum of the particles allows the maintenance of a sharp particle size distribution during growth.

The particle size distribution of the semiconductor nanocrystals (including, e.g., semiconductor nanocrystals) can be further refined by size selective precipitation with a poor solvent for the semiconductor nanocrystals, such as methanol/butanol. For example, semiconductor nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected semiconductor nanocrystal (e.g., semiconductor nanocrystal) population preferably has no more than a 15% rms deviation from mean diameter, more preferably 10% rms deviation or less, and most preferably 5% rms deviation or less.

A semiconductor nanocrystal is capable of emitting light upon excitation. A semiconductor nanocrystal can be excited by irradiation with an excitation wavelength of light, by electrical excitation, or by other energy transfer.

In general, semiconductor nanocrystals, including those prepared by the present method, can have an average particle size in a range from about 1 to about 1000 nanometers (nm), and preferably in a range from about 1 to about 100 nm. In certain embodiments, semiconductor nanocrystals have an average particle size in a range from about 1 to about 20 nm (e.g., such as about 2, 3, 4, 5, 6, 7, 8, 9, 10, 11, 12, 13, 14, 15, 16, 17, 18, 19, or 20 nm). In certain embodiments, semiconductor nanocrystals have an average particle size in a range from about 1 nm to about 20 nm or about 1 nm to about 10 nm. Semiconductor nanocrystals can have an average diameter less than about 150 Angstroms (Á). In certain embodiments, semiconductor nanocrystals having an average diameter in a range from about 12 to about 150 Á can be particularly desirable. However, depending upon the composition, structure, and desired emission wavelength of the semiconductor nanocrystal, the average diameter may be outside of these ranges. The size of a nanocrystal can be determined, for example, by direct transmission electron microscope measurement. Other known techniques can also be used to determine nanocrystal size.

Nanocrystals can have various shapes. Examples of the shape of a nanocrystal include, but are not limited to, sphere, rod, disk, tetrapod, other shapes, and/or mixtures thereof.

A semiconductor material may comprise a compound, a doped compound, an undoped compound, and/or an alloy. A nanocrystal core surrounded by a shell is also referred to as having a “core/shell” structure.

Semiconductor nanocrystals can have optical properties arising from quantum confinement. The particular composition(s), structure, and/or size of a semiconductor nanocrystal can be selected to achieve the desired wavelength of light to be emitted from the semiconductor nanocrystal upon stimulation with a particular excitation source. Semiconductor nanocrystals may be tuned to emit light across the spectrum, e.g., ultraviolet, visible, or infra-red regions, by changing their size. A monodisperse population of semiconductor nanocrystals can emit light spanning a narrow range of wavelengths.

The emission from a semiconductor nanocrystal capable of emitting light can be a Gaussian emission band, which is preferably narrow, and that can be tuned through the complete wavelength range of the ultraviolet, visible, or infra-red regions of the spectrum by varying the size of the semiconductor nanocrystal, the composition of the semiconductor nanocrystal, or both. Spectral emissions in a narrow range of no greater than about 75 nm, preferably no greater than about 60 nm, more preferably no greater than about 40 nm, and most preferably no greater than about 30 nm full width at half max (FWHM) for such semiconductor nanocrystals that emit in the visible are desirable.

Semiconductor nanocrystals prepared according to the present invention may be used in various applications. According to one aspect, semiconductor nanocrystals prepared according to the methods described herein may be used in photoluminescent (PL) applications where semiconductor nanocrystals are excited optically and the optical excitation is downconverted via emission from the semiconductor nanocrystals. According to this aspect, exemplary applications include devices or systems where an LED light source is used, for example solid-state lighting, LED Backlights (LED-BLU), Liquid Crystal Displays (LCD) and the like. According to an additional aspect, semiconductor nanocrystals prepared according to the methods described herein may be used in a device or system where a light source is downconverted to other wavelengths (e.g., but not limited to, solar concentrators or downconverters where sunlight is converted to specific wavelengths tuned to the highest efficiency window of the solar cells used in the system). Additional applications include plasma based systems where high energy plasma emission can excite a semiconductor nanocrystal downconverter, taggants, bio-labeling or imaging application, and barcoding or security/covert labeling applications. According to an additional aspect, semiconductor nanocrystals prepared according to the present invention may be used in electroluminescent (EL) applications where semiconductor nanocrystals are excited electrically and the excitation results in emission from the semiconductor nanocrystals. According to this aspect, exemplary applications include direct charge injection into the semiconductor nanocrystals generating semiconductor nanocrystal excited states and subsequent semiconductor nanocrystal emission, energy transfer from other semiconductor materials within the device to the semiconductor nanocrystals, generating an excited state and subsequent semiconductor nanocrystal emission and the like. According to an additional aspect, semiconductor nanocrystals prepared according to the present invention may be used in photovoltaic (PV) applications where the semiconductor nanocrystal materials are excited optically and the excitation results in current generation and/or a voltage due to carrier extraction from the semiconductor nanocrystals.

Additional information that may be useful in connection with the present disclosure and the inventions described herein is included in International Application No. PCT/US2008/10651 of Breen et al, filed 12 Sep. 2008, entitled “Functionalized Nanoparticles And Method”; and International Application No. PCT/US2007/024320 of Clough et al, filed 21 Nov. 2007, entitled “Nanocrystals Including A Group IIIa Element And A Group Va Element, Method, Composition, Device And Other Products”; International Application No. PCT/US2012/038198, filed May 16, 2012, entitled “Method for Preparing Semiconductor Nanocrystals”; International Application No. PCT/US2009/002789 of Coe-Sullivan et al, filed 6 May 2009, entitled: “Solid State Lighting Devices Including Quantum Confined Semiconductor Nanoparticles, An Optical Component For A Solid State Light Device, And Methods”, and International Application No. PCT/US2011/047284 of Sadasivan et al, filed 10 Aug. 2011 entitled “Quantum Dot Based Lighting” each of the foregoing being hereby incorporated herein by reference in its entirety.

Solid state external quantum efficiency” (also referred to herein as “EQE” or “solid state photoluminescent efficiency”) can be measured in a 12″ integrating sphere using a NIST traceable calibrated light source, using the method developed by de Mello et al., Advanced Materials 9(3):230 (1997), which is hereby incorporated by reference. Such measurements can also be made with a QEMS from LabSphere (which utilizes a 4 inch sphere; e.g. QEMS-2000: World Wide Website laser2000.nl/upload/documenten/fop_{—}21-en2.pdf).

As used herein, the singular forms “a”, “an” and “the” include plural unless the context clearly dictates otherwise. Thus, for example, reference to an emissive material includes reference to one or more of such materials.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method for preparing a semiconductor nanocrystal, comprising:
forming a reaction mixture comprising injecting one or more first semiconductor nanocrystal precursors including one or more Group V elements and one or more Group VI elements into a mixture including one or more second semiconductor nanocrystal precursors including one or more Group II elements and one or more Group III elements at a first temperature; and
reacting the first and second semiconductor nanocrystal precursors in the reaction mixture at a second temperature for a period time sufficient to form a semiconductor nanocrystal core comprising at least a portion of the one or more Group II elements, one or more Group III elements, one or more Group V elements, and one or more Group VI elements included in the first and second semiconductor nanocrystal precursors, wherein the second temperature is greater than the first temperature.

2. A method in accordance with claim 1 wherein the first temperature is greater than about 170° C.

3. A method in accordance with claim 2 wherein the second temperature is at least 10° C. greater than the first temperature.

4. A method in accordance with claim 1 wherein the second temperature is in a range from about 255° C. to about 325° C. and is at least 10° C. greater than the first temperature.

5. A method in accordance with claim 1 wherein the mixture further includes a carboxylic acid compound.

6. (canceled)

7. A method in accordance with claim 1 wherein the reacting step is carried out at a single reaction temperature.

8-9. (canceled)

10. A method in accordance with claim 1 wherein the semiconductor nanocrystal core comprises an alloy including one or more Group II elements, one or more Group III elements, one or more Group V elements, and one or more Group VI elements.

11. A method in accordance with claim 1 wherein the method further comprises overcoating the semiconductor nanocrystal cores with one or more inorganic semiconductor materials.

12. A method in accordance with claim 11 wherein the semiconductor nanocrystal cores are isolated prior to the overcoating step.

13. A method in accordance with claim 11 wherein the overcoating comprises more than one layer wherein a layer comprises an inorganic semiconductor material that is the same as or different from that in another layer.

14. (canceled)

15. A method in accordance with claim 1 wherein the molar ratio of Group II elements to Group III elements to Group V elements to Group VI elements included in the precursors in the reaction mixture is approximately 1 to 1 to 1 to 1.

16. A method in accordance with claim 5 wherein the molar ratio of Group II elements to Group III elements to Group V elements to Group VI elements to COO⁻ groups is approximately 1 to 1 to 1 to 1 to 2.

17. A method in accordance with claim 1 wherein the one or more Group II elements include zinc.

18. A method in accordance with claim 1 wherein the one or more Group III elements include indium.

19. A method in accordance with claim 1 wherein the one or more Group III elements include indium and gallium.

20. A method in accordance with claim 1 wherein the one or more Group V elements include phosphorus.

21. A method in accordance with claim 1 wherein the one or more Group VI elements include sulfur.

22. A method in accordance with claim 19 wherein inclusion of gallium provides a blue shift in the peak emission wavelength of the resulting semiconductor nanocrystal core compared to one prepared under similar reaction conditions from a reaction mixture that does not include gallium but is otherwise the same.

23. A method in accordance with claim 1 wherein the reaction mixture includes a Group II element including zinc, Group III elements including indium and gallium, a Group V element including phosphorus, and a Group VI element including sulfur, wherein the molar ratio of zinc to (indium plus gallium) to phosphorus to sulfur included in the first and second semiconductor nanocrystal precursors is approximately 1 to 1 to 1 to 1.

24. A method in accordance with claim 23 wherein the molar ratio of indium to gallium is in a range from 1:0.5 to 1.1.

25. A method for preparing a semiconductor nanocrystal, comprising:
forming a reaction mixture comprising injecting one or more first semiconductor nanocrystal precursors including a Group V element comprising phosphorus and a Group VI element comprising sulfur into a mixture including second semiconductor nanocrystal precursors including a Group II element comprising zinc and Group III elements comprising indium and gallium at a first temperature in a range from about 200° C. to 250° C.; and
reacting the first and second semiconductor nanocrystal precursors in the reaction mixture at a second temperature in a range from about 260° C. to about 300° C. for a period time sufficient to form semiconductor nanocrystal cores comprising at least a portion of the phosphorus, sulfur, zinc, indium, and gallium included in the first and second semiconductor nanocrystal precursors; and
overcoating the semiconductor nanocrystal cores with one or more inorganic semiconductor materials.

26. A method in accordance with claim 25 wherein the reaction mixture further includes a carboxylic compound.

27. A method in accordance with claim 25 wherein the method further comprises isolating the semiconductor nanocrystal cores prior to the overcoating step.

28-35. (canceled)
